(19) United States
(12) Patent Application Publication
(10) Pub. No.: US 2025/0343283 A1
(43) Pub. Date: Nov. 6, 2025

(54) SMART BATTERY MANAGEMENT

(71) Applicant: CPS Technology Holdings LLC, New York, NY (US)

(72) Inventor: Zhihong JIN, Pewaukee, WI (US)

(21) Appl. No.: 18/864,175

(22) PCT Filed: May 18, 2023
(86) PCT No.: PCT/US2023/022660

§ 371 Date: Nov. 8, 2024

Related U.S. Application Data
(60) Provisional application No. 63/346,567, filed on May 27, 2022.

(51) Int. Cl. H01M 10/42; H01M 10/06; H01M 10/48

(52) U.S. Cl. CPC H01M 10/425; H01M 10/06; H01M 10/482; H01M 10/486; H01M 2010/4271

(57) ABSTRACT

A battery management system (BMS) electrically connectable to a lead-acid battery having one or more cells is described. The BMS includes processing circuitry configured to determine one or both of a state of function (SoF) and a state of charge (SoC) based on one or more parameters. The one or more parameters include at least one parameter associated with the one or more cells of the lead-acid battery. One or more actions are performed based on the determination.

### TECHNICAL FIELD

This disclosure relates to energy storage units such as batteries, and in particular to battery management systems.

### BACKGROUND

Batteries are an essential part of many devices, including motor vehicles. Motor vehicles are typically equipped with one or more batteries, e.g., a lead acid battery, used to both start the vehicle's motor as well as to power the other systems of the vehicle, e.g., charging system, operation while running, lighting, accessories, etc. Reliability of batteries generally depends on the battery health, i.e., condition of the battery. However, many typical batteries do not provide information about battery health, e.g., usable to predict battery health degradation, potential failures, etc. In other words, many typical batteries degrade over time and fail suddenly (e.g., fail to provide requisite power) without warning to the user/owner of the battery. Accordingly, real-time battery reliability/condition is unknown the user/owner, and the user/owner cannot take actions to prevent potential battery failures.

### SUMMARY

Some embodiments advantageously provide a method, apparatus, and system for determining and/or communicating, such as via a battery management system (BMS), one or more parameters associated with a battery. The parameters may be associated with one or more battery states and/or used to determine (and/or diagnose and/or forecast) one or more battery states and/or other parameters. Determining one or more battery states may include determining optimized states, state of health (SoH), abuse/faults associated with the battery, e.g., to keep the battery in one or more optimized states, communicate parameters and/or other determinations such as when a preventive battery replacement is suggested (and/or necessary). Such determinations are beneficial at least because the user (and/or owner and/or manufacturer) of the battery may be informed of battery parameters/states and avoid unexpected battery failures. In some embodiments, the parameters are determined for at least one battery cell of the battery.

According to one aspect, a battery management system (BMS) electrically connectable to a lead-acid battery having one or more cells is described. The BMS includes processing circuitry configured to determine one or both of a state of function (SoF) and a state of charge (SoC) based on one or more parameters. The one or more parameters include at least one parameter associated with the one or more cells of the lead-acid battery. One or more actions are performed based on the determination.

In some embodiments, determining the SoF comprises determining a design current of the one or more cells based on one or more characteristics of the one or more cells.

In some other embodiments, determining the SoF further includes determining a pack current based on a pack voltage, a pack open circuit voltage, OCV, and a pack impedance corresponding to the one or more cells.

In some embodiments, determining the SoF further includes determining a cell current based on a cell voltage, a cell OCV, and a cell impedance corresponding to the one or more cells.

In some other embodiments, determining the SoF further includes determining a current limit, the current limit being a minimum of one or more of the design current, the pack current, and the cell current.

In some embodiments, determining the SoF is based on a power limit determined based on the current limit and the voltage limit.

In some other embodiments, determining the SoF further includes determining a power limit based on the current limit and the voltage limit.

In some embodiments, the SoC is determined as:

$$SoC ( t ) = SoC ( t 0 ) - {\int }_{t 0}^{t} \frac{I ( t )}{Q ( t )} dt$$

SoC(t) being the SoC in time;
SoC(t0) being the SoC at a first time value
I(t) being a cell current in time; and
Q(t) being a capacity.

In some other embodiments, determining the SOC includes determining an OCV correction, the OCV correction being based on one or more OCV values. The one or more OCV values are based on a plurality of SoC percentages and a plurality of temperature values associated with the lead-acid battery.

In some embodiments, performing one or more actions includes causing transmission of a first message including one or both of the SoF and the SoC using a controller area network (CAN) protocol, causing transmission of a second message including at last one parameter associated with one or both of the SoF and the SoC, and performing a battery operation action.

According to another aspect, a lead-acid battery is described. The lead-acid battery includes one or more cells, one or more leads, and a battery management system (BMS). Each one of the one or more leads is electrically connected to one cell of the one or more cells. The BMS is electrically connected to the one or more cells via the one or more leads. The BMS includes processing circuitry configured to determine one or both of a state of function (SoF) and a state of charge (SoC) based on one or more parameters, where the one or more parameters include at least one parameter associated with the one or more cells, and perform one or more actions based on the determination.

In some embodiments, determining the SoF includes determining a design current of the one or more cells based on one or more characteristics of the one or more cells.

In some other embodiments, determining the SoF further includes determining a pack current based on a pack voltage, a pack open circuit voltage (OCV) and a pack impedance corresponding to the one or more cells.

In some embodiments, determining the SoF further includes determining a cell current based on a cell voltage, a cell OCV, and a cell impedance corresponding to the one or more cells.

In some other embodiments, determining the SoF further includes determining a current limit, where the current limit is a minimum of one or more of the design current, the pack current, and the cell current.

In some embodiments, determining the SoF further includes determining a voltage limit based on the current limit.

In some other embodiments, determining the SoF is based on a power limit determined based on the current limit and the voltage limit.

In some embodiments, the SoC is determined as:

$$SoC ( t ) = SoC ( t 0 ) - {\int }_{t 0}^{t} \frac{I ( t )}{Q ( t )} dt$$

SoC(t) being the SoC in time;
SoC(t0) being the SoC at a first time value
I(t) being a cell current in time; and
Q(t) being a capacity.

In some other embodiments, determining the SOC includes determining an OCV correction. The OCV correction is based on one or more OCV values. The one or more OCV values are based on a plurality of SoC percentages and a plurality of temperature values associated with the lead-acid battery.

In some embodiments, performing one or more actions includes causing transmission of a first message comprising one or both of the SoF and the SoC using a controller area network (CAN) protocol, causing transmission of a second message comprising at last one parameter associated with one or both of the SoF and the SoC, and performing a battery operation action.

According to an aspect, a method in a battery management system (BMS) electrically connectable to a lead-acid battery having one or more cells is described. The method includes determining one or both of a state of function (SoF) and a state of charge (SoC) based on one or more parameters, where the one or more parameters include at least one parameter associated with the one or more cells of the lead-acid battery, and performing one or more actions based on the determination.

In some embodiments, determining the SoF includes determining a design current of the one or more cells based on one or more characteristics of the one or more cells.

In some other embodiments, determining the SoF further includes determining a pack current based on a pack voltage, a pack open circuit voltage (OCV) and a pack impedance corresponding to the one or more cells.

In some embodiments, determining the SoF further includes determining a cell current based on a cell voltage, a cell OCV, and a cell impedance corresponding to the one or more cells.

In some other embodiments, determining the SoF further comprises determining a current limit, where the current limit is a minimum of one or more of the design current, the pack current, and the cell current.

In some embodiments, determining the SoF further includes determining a voltage limit based on the current limit.

In some other embodiments, determining the SoF is based on a power limit determined based on the current limit and the voltage limit.

In some embodiments, the SoC is determined as:

$$SoC ( t ) = SoC ( t 0 ) - {\int }_{t 0}^{t} \frac{I ( t )}{Q ( t )} dt$$

SoC(t) being the SoC in time;
SoC(t0) being the SoC at a first time value
I(t) being a cell current in time; and
Q(t) being a capacity.

In some other embodiments, determining the SOC includes determining an OCV correction. The OCV correction is based on one or more OCV values. The one or more OCV values are based on a plurality of SoC percentages and a plurality of temperature values associated with the lead-acid battery.

In some embodiments, performing one or more actions includes transmitting a first message comprising one or both of the SoF and the SoC using a controller area network (CAN) protocol, transmitting a second message comprising at last one parameter associated with one or both of the SoF and the SoC, and performing a battery operation action.

### BRIEF DESCRIPTION OF THE DRAWINGS

A more complete understanding of embodiments described herein, and the attendant advantages and features thereof, will be more readily understood by reference to the following detailed description when considered in conjunction with the accompanying drawings wherein:

FIG. 1 shows a block diagram of an example battery constructed in accordance with the principles of present disclosure;

FIG. 2 shows an example system in accordance with the principles of present disclosure;

FIG. 3 is a block diagram of some entities in the system according to some embodiments of the present disclosure;

FIG. 4 shows example elements of a process (e.g., algorithm, method) to determine/communicate one or more parameters in accordance with the principles of present disclosure;

FIG. 5 shows example elements of a process for determining information associated with a parameter in accordance with the principles of present disclosure;

FIG. 6 shows an example lookup graph in accordance with the principles of present disclosure;

FIG. 7 shows a table including example messages in accordance with the principles of present disclosure; and

FIG. 8 shows an example method in accordance with the principles of the present disclosure.

### DETAILED DESCRIPTION

Before describing in detail exemplary embodiments, it is noted that the embodiments reside primarily in combinations of apparatus components and processing steps related to determining one or more parameters associated with a battery such as used in connection with, for example, a lead acid or Li-Ion battery. The determination may be performed by any one a battery management system (BMS), device, server, etc. Accordingly, the system and method components have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

As used herein, relational terms, such as “first” and “second,” “top” and “bottom.” and the like, may be used solely to distinguish one entity or element from another entity or element without necessarily requiring or implying any physical or logical relationship or order between such entities or elements. The terminology used herein is for the purpose of describing particular embodiments only and is not intended to be limiting of the concepts described herein. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In embodiments described herein, the joining term, “in communication with” and the like, may be used to indicate electrical or data communication, which may be accomplished by physical contact, induction, electromagnetic radiation, radio signaling, infrared signaling or optical signaling, for example. One having ordinary skill in the art will appreciate that multiple components may interoperate and modifications and variations are possible of achieving the electrical and data communication.

In some embodiments, the term “parameter” may refer to a numerical or other value, e.g., an input, an output, etc. The parameter may be measurable and/or determinable and/or communicated and/or associated with a battery and/or battery component and/or other devices/systems. Parameter may also refer to a quantity selectable for a predetermined situation and/or be based on one or more parameters/states/variable. In a nonlimiting example, parameter may comprise voltage, current, power, temperature, pressure, etc. Further, a parameter may be a state. The term state may refer to a battery state and/or state associated with other devices/systems. In some embodiments, the term state of charge (SoC) is used and may refer to a level of charge of a battery (and/or any other components of a battery such as a cell). The SoC may be relative to the capacity of the battery (and/or any other components of a battery such as a cell), e.g., expressed as a percentage. In some other embodiments, the term state of function (SoF) is used and may refer to an ability of the battery to perform a predetermined function and/or a battery readiness to perform one or more functions. SoF may be the battery readiness in terms of usable energy such as being based on SoC in relation to available capacity.

In some embodiments, an action may be performed. The action may comprise transmitting/receiving parameters using one or more communication protocols, performing a battery operation action, triggering a component to perform another action, etc. Performing a battery operation action may comprise enabling a battery operation mode (e.g., active, inactive, sleeping, power saving mode, etc.). The battery operation mode may also trigger the battery to enable/disable battery charging, allow the battery to provide power, prevent the battery from providing power, etc. In some embodiments, the action may comprise determining information about battery health, e.g., usable to predict battery health degradation, potential failures, etc. In some other embodiments, the action may comprise warning a user/owner of the battery, e.g., of a real-time battery reliability/condition, where the user can take actions to prevent potential battery failures.

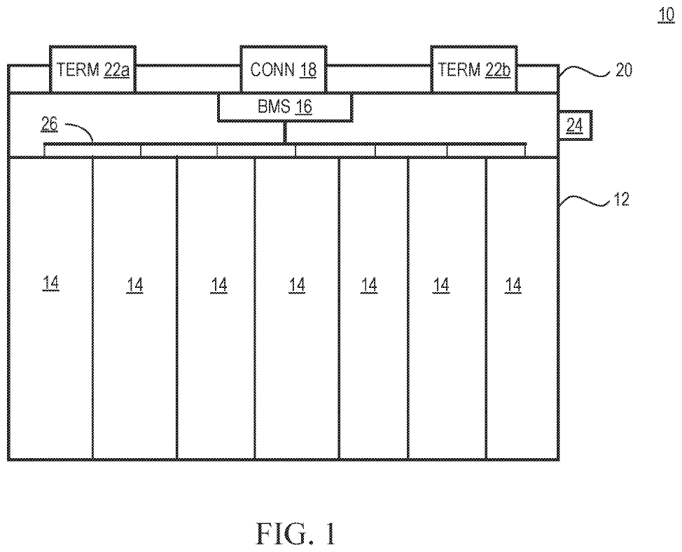

Referring now to the drawing figures in which like reference numbers refer to like elements, there is shown in FIG. 1, a battery 10 constructed in accordance with the principles of the present disclosure. Battery 10 includes a housing 12 into which one or more cells 14 are positioned. The cells 14 may be electrically interconnected (not shown in the FIGS), such as via an electrically conductive bus bar system which electrically interconnects the cells 14 in an electrically serial, electrically parallel or combination of electrically serial and parallel manner, depending on the intended voltage and current requirements.

A battery monitoring system (BMS) 16 may be included. In some embodiments, the BMS 16 may determine certain battery parameters, e.g., voltage, temperature, pressure, power, current, etc., and provide the data to an external system. BMS 16 may also be connected to one or more cells 14. For example, BMS 16 may be physically and/or electrically connected to a plurality of leads 26 (e.g., lead assembly), where each lead 26 is physically and/or electrically connected to a cell 14. That is, BMS 16 may be configured to determine (e.g., measure) one or more parameters of each cell 14, via a lead 26. The plurality of leads 26 may be comprised (e.g., be part of) battery 10 and/or BMS 16. Further, BMS 16 may include and/or be coupled to a monitoring connector 18 that allows for an external connection such as to the vehicle's data bus, or to some other communication device. The monitoring connector 18 can, in some embodiments, be integrated with the housing 12, such as in a cover 20 of the housing 12. Battery 10 also includes terminals, such as a negative terminal 22a and a positive terminal 22b (collectively referred to as terminals 22) to provide the contact points for electrical connection of the battery 10 to the vehicle to provide the auxiliary power to the vehicle. Terminals 22 are arranged to protrude through housing 12, such as protruding through cover 20. Terminals 22 may be electrically connected to the bus bars inside housing 12 and/or directly connected to the cells 14 (not shown in the FIGS). In some embodiments, housing 12 includes one or more vent holes 24 to allow venting from one or more of the cells 14.

Battery 10 can be arranged to provide many power capacities and physical sizes, and to operate under various parameters and parameter ranges. It is also noted that implementations of battery 10 some can be scaled to provide various capacities. Power capacity scaling can be accomplished, for example, by using higher or lower power capacity cells 14 in the housing 12, and/or by using fewer or more cells 14 in the housing 12. In some embodiments, battery 10 may be incorporated as part of a vehicle such as an electric vehicle (EV) or another type of vehicle where battery power is needed. Other electrical parameters of the battery 10 can be adjusted/accommodated by using cells 14 that may cumulatively have the desired operational characteristics, e.g., voltage, charging capacity/rate, discharge rate, etc. Thermal properties can be managed based on cell 14 characteristics, the use of heat sinks and/or thermal energy discharge plates, etc., within or external to the housing 12.

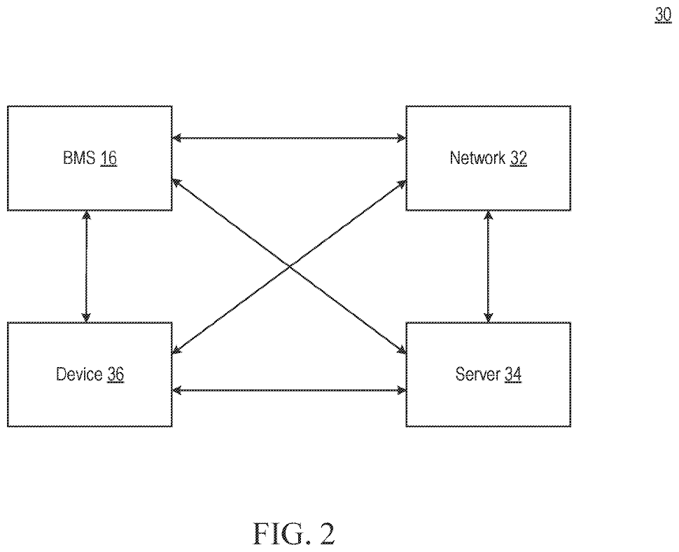

FIG. 2 shows an example system 30 in accordance with the principles of present disclosure. System 30 may include one or more of each of the following: BMS 16, network 32, server 34, device 36. In this nonlimiting example, BMS 16 may be configured to communicate with network 32 and/or server 34 and/or device 36. Network 32 may be configured to provide communication functions and/or network functions to BMS 16 and/or server 34 and/or device 36 such as access to one or more servers (e.g., server 34) and/or server functions. Server 34 may be any server, computer, client device, network node, network device, etc. Server 34 may be configured to communicate with BMS 16 and/or network 32 and/or device 36. Server 34 may be standalone, integrated with BMS 16 and/or network 32 and/or device 36, etc. Similarly, BMS 16 may be standalone, part of a device 36, part of battery 10, integrated with network 32 and/or server 34, etc. Further, BMS 16 (and/or network 32 and/or server 34 and/or device 36) may be configured to perform any of the steps and/or tasks and/or methods and/or processes and/or features described herein, e.g., such as determining one or more parameters of a battery 10 and/or performing communication functions such as transmitting/receiving one or more messages associated with one or more parameters. BMS 16 may include processing circuitry, such as a processing unit (e.g., processor) and memory, to perform one or more functions described herein. BMS 16 may include communication units (e.g., communication interfaces) to communicate with sensors that monitor the cells 14, and other operational parameters of the battery 10, and/or communicate with external elements such as network 32 and/or server 34 and/or device 36.

In particular, in addition to or instead of a processor, such as a central processing unit, and memory, the processing circuitry may comprise integrated circuitry for processing and/or control, e.g., one or more processors and/or processor cores and/or FPGAs (Field Programmable Gate Array) and/or ASICs (Application Specific Integrated Circuitry) adapted to execute instructions. The processor may be configured to access (e.g., write to and/or read from) memory, which may comprise any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory).

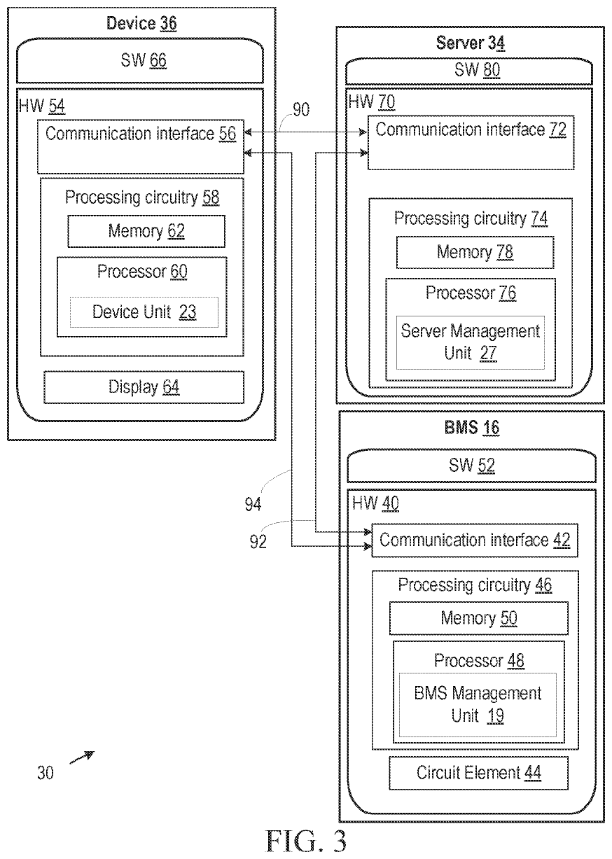

Example implementations, in accordance with an embodiment, of BMS 16, device 36, and server 34 discussed in the preceding paragraphs will now be described with reference to FIG. 3. BMS 16 may have hardware 40 that may include a communication interface 42 that is configured to communicate with one or more entities in system 30 via wired and/or wireless communication. The communication may be protocol based communications.

The hardware 40 includes processing circuitry 46. The processing circuitry 46 may include a processor 48 and memory 50. In particular, in addition to or instead of a processor, such as a central processing unit, and memory, the processing circuitry 46 may comprise integrated circuitry for processing and/or control, e.g., one or more processors and/or processor cores and/or FPGAs (Field Programmable Gate Array) and/or ASICs (Application Specific Integrated Circuitry) adapted to execute instructions. The processor 48 may be configured to access (e.g., write to and/or read from) memory 50, which may comprise any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory). Hardware 40 may also comprise one or more circuit elements 44 such as resistors, capacitors, inductors, diodes, transistors, ground connections, source elements, sink elements, etc. Circuit elements 44 may be arranged in any configuration or connection such as series, parallel, combinations thereof, etc., and may be connected to any other device such as a component of system 30.

Thus, the BMS 16 may further comprise software 52, which is stored in, for example, memory 50, or stored in external memory (e.g., database, etc.) accessible by the BMS 16. The software 52 may be executable by the processing circuitry 46.

The processing circuitry 46 may be configured to control any of the methods and/or processes described herein and/or to cause such methods, and/or processes to be performed, e.g., by BMS 16. The processor 48 corresponds to one or more processors 48 for performing BMS 16 functions described herein. The BMS 16 includes memory 50 that is configured to store data, programmatic software code and/or other information described herein. In some embodiments, the software 52 may include instructions that, when executed by the processor 48 and/or processing circuitry 46, causes the processor 48 and/or processing circuitry 46 to perform the processes described herein with respect to BMS 16. For example, the processing circuitry 46 of the BMS 16 may include BMS management unit 19 that is configured to perform any step and/or task and/or process and/or method and/or feature described in the present disclosure, e.g., determining one or more parameters, steps, and/or processes associated with battery 10. While BMS management unit 19 is illustrated as being part of BMS 16, BMS management unit 19 and associated functions described herein may be implemented in a device separate from BMS 16 such as in battery 10 or another device.

Device 36 may have hardware 54 that may include a communication interface 56 that is configured to communicate with one or more entities in system 30 (and/or outside of system 30) via wired and/or wireless communication. The communication may be protocol based communication. Device 36 may also be configured to electrically connect to battery 10, e.g., to power device 36 and/or receive at least one parameter (and/or parameter data) from battery 10 and/or display the at least one parameter.

The hardware 54 includes processing circuitry 58. The processing circuitry 58 may include a processor 60 and memory 62. In particular, in addition to or instead of a processor, such as a central processing unit, and memory, the processing circuitry 58 may comprise integrated circuitry for processing and/or control, e.g., one or more processors and/or processor cores and/or FPGAs (Field Programmable Gate Array) and/or ASICs (Application Specific Integrated Circuitry) adapted to execute instructions. The processor 60 may be configured to access (e.g., write to and/or read from) memory 62, which may comprise any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory).

Device 36 may further comprise software 66, which is stored in, for example, memory 62, or stored in external memory (e.g., database, etc.) accessible by the device 36. The software 66 may be executable by the processing circuitry 58.

The processing circuitry 58 may be configured to control any of the methods and/or processes described herein and/or to cause such methods, and/or processes to be performed, e.g., by device 36. The processor 60 corresponds to one or more processors 60 for performing device 36 functions described herein. The device 36 includes memory 62 that is configured to store data, programmatic software code and/or other information described herein. In some embodiments, the software 66 may include instructions that, when executed by the processor 60 and/or processing circuitry 58, causes the processor 60 and/or processing circuitry 58 to perform the processes described herein with respect to device 36. For example, the processing circuitry 58 of device 36 may include device unit 23 configured to perform any step and/or task and/or process and/or method and/or feature described in the present disclosure, e.g., determining one or more parameters, steps, and/or processes associated with battery 10. Device 36 may also include display 64 configured to display an indication associated with a measured/determined at least one parameter, e.g., associated with battery 10. The at least one parameter may include state of charge, voltage, current, etc. Display 64 may comprise a light such as a light emitting diode (LED), a monitor, a screen, and/or any other type of display.

In some embodiments, device 36 and/or any of its components such as display 64 may be comprised in BMS 16 (and/or battery 10) and/or be powered by BMS 16 (and/or battery 10).

Further, server 34 includes hardware 70, and the hardware 70 may include a communication interface 72 for performing wired and/or wireless communication with BMS 16 and/or device 36 and/or any other device. For example, communication interface 72 of server 34 may communicate with communication interface 56 of device 36 via communication link 90. In addition, communication interface 72 of server 34 may communicate with communication interface 42 of BMS 16 via communication link 92. Similarly, communication interface 42 may communicate with communication interface 56 via communication link 94. At least one of communication links 90, 92, 94 may refer to a wired/wireless connection (such as WiFi, Bluetooth, etc.).

In the embodiment shown, the hardware 70 of server 34 includes processing circuitry 74. The processing circuitry 74 may include a processor 76 and a memory 78. In particular, in addition to or instead of a processor, such as a central processing unit, and memory, the processing circuitry 74 may comprise integrated circuitry for processing and/or control, e.g., one or more processors and/or processor cores and/or FPGAs (Field Programmable Gate Array) and/or ASICs (Application Specific Integrated Circuitry) adapted to execute instructions. The processor 76 may be configured to access (e.g., write to and/or read from) the memory 78, which may comprise any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory).

Thus, the server 34 further has software 80 stored internally in, for example, memory 78, or stored in external memory (e.g., database, etc.) accessible by the server 34 via an external connection. The software 80 may be executable by the processing circuitry 74. The processing circuitry 74 may be configured to control any of the methods and/or processes described herein and/or to cause such methods, and/or processes to be performed, e.g., by server 34. Processor 76 corresponds to one or more processors 76 for performing server 34 functions described herein. The memory 78 is configured to store data, programmatic software code and/or other information described herein. In some embodiments, the software 80 may include instructions that, when executed by the processor 76 and/or processing circuitry 74, causes the processor 76 and/or processing circuitry 74 to perform the processes described herein with respect to server 34. For example, processing circuitry 74 of server 34 may include server management unit 27 that is configured to perform one or more server 34 functions as described herein, e.g., determining one or more parameters, steps, and/or processes associated with battery 10.

In some embodiments, device 36 may be comprised in a BMS 16 and/or battery 10 (as shown in FIG. 1) and/or be standalone. In some other embodiments, device 36 may be configured to perform any BMS function. In some embodiments, device 36 and battery 10 are comprised in a vehicle, and device 36 may be connectable to battery 10 and/or BMS 16.

Although FIG. 3 shows one or more “units” such as BMS management unit 19, device unit 23, server management unit 27 as being within a respective processor, it is contemplated that these units may be implemented such that a portion of the unit is stored in a corresponding memory within the processing circuitry. In other words, the units may be implemented in hardware, software or in a combination of hardware and software within the processing circuitry.

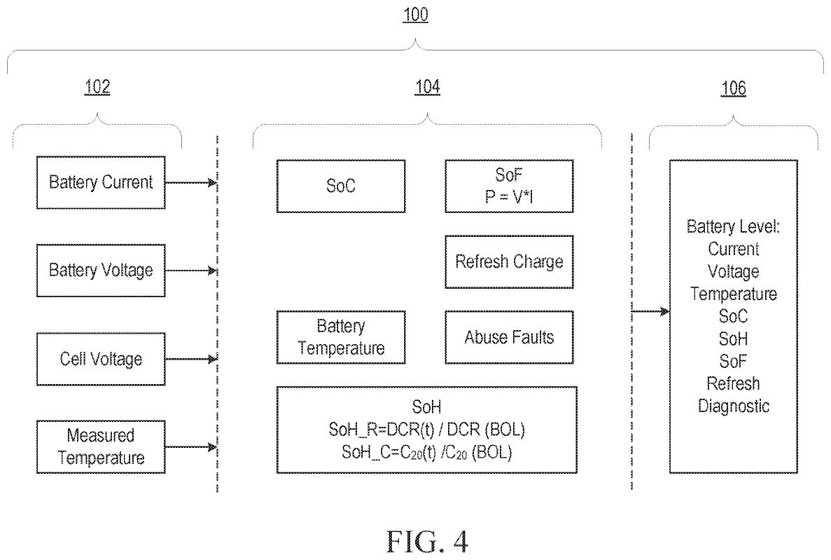

FIG. 4 shows example elements of a process (e.g., algorithm, method) to determine/communicate one or more parameters such as to server 34 and/or network 32 and/or device 36. The example process may be performed by any one of the components of system 30 (e.g., BMS 16) and may comprise receiving one or more input parameters 102 and/or determining parameters 104 and/or providing one or more output parameters 106. Input parameters 102 may include battery current, battery voltage, cell voltage, temperature (e.g., measured temperatures), etc. Input parameters 102 such as voltage, current, temperature, etc. may be measured per cell 14 such as via leads 26. The method may comprise determining parameters 104 such as SoC, SoF, refresh charge, battery temperature, abuse faults, SoH, e.g., based on the input parameters 102. Output parameters 106 may include current, voltage, temperature, SoC, SoH, SoF, refresh charge, diagnostics, etc., e.g., based on the parameters 104. In some embodiments, BMS 16 may be configured to perform one or more steps/blocks shown in FIG. 4, which may include determining and/or communicating to another device one or more of parameters 104 (and/or input parameters 102 and/or output parameters 106), e.g.: SoC, SoF, battery temperature, SoH, refresh charge, abuse faults, etc., e.g., based on the inputs. BMS 16 may be configured to provide the outputs (e.g., by determining and/or communicating at least one of the outputs).

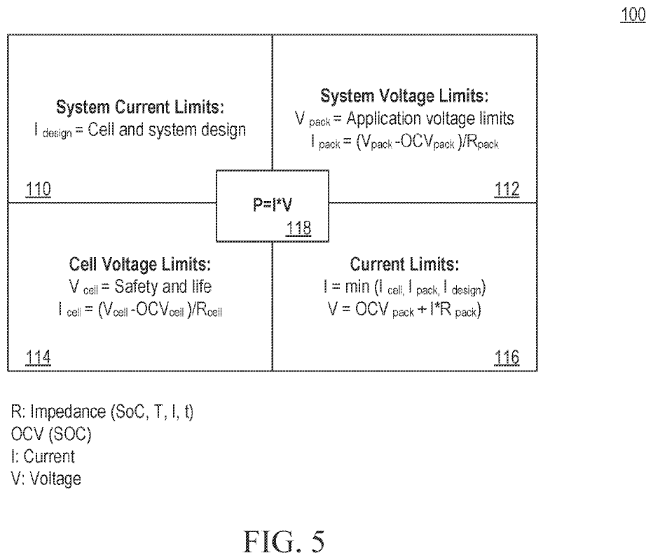

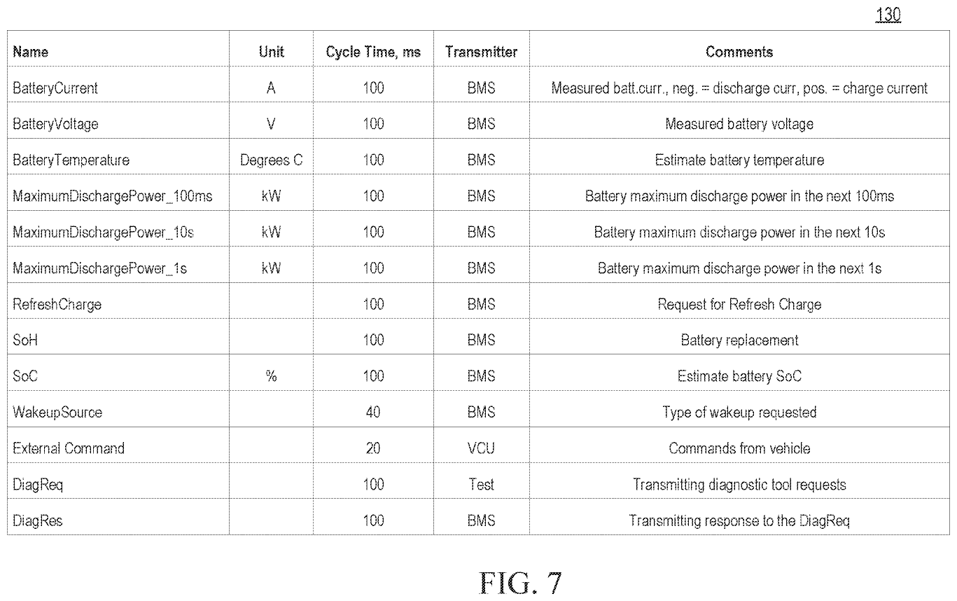

For example, BMS 16 may be configured to perform one or more of the algorithms of FIG. 4 such as to determine and/or communicate and/or report:
battery level of outputs to messages described with respect to FIG. 7;
the battery outputs by using battery and cell level measurement data;
SoH which may be an estimate of battery resistance change and/or capacity change using real time measurement data and tracked battery usage information;
when the battery shall (i.e., should) be replaced;
SoF which may be an estimate of power limits based on the battery SoC, SoH, and/or temperature;
additional information associated with SoF, as described with respect to FIG. 5;
refresh charge algorithm, e.g., to determine when the battery shall be charged based on the battery and cell SoCs and battery usage history;
the battery abuse conditions, which can be tracked by BMS 16; and
communication protocol set faults, which can be recorded by BMS 16.

FIG. 5 shows example parameters 100 associated with SoF, e.g., power limitation estimation, system current limits, system voltage limits, cell voltage limits, current limits. An example process using the example parameters 100 may be performed by BMS 16. The SoF power limit estimation may depend on the most constrained conditions. The SoF power limit estimation may consider (i.e., may be determined based on) the maximum current ability of the system designs, the voltage limitations of the system (i.e., battery 10, system 30) and/or vehicle applications and/or the performance limits of cell(s) 14. For example, power (P) limit estimation (e.g., P=I*V, where I refers to current, and V refers to voltage) may be determined based on at least one of system current limits 110, system voltage limits 112, cell voltage limits 114, current limits 116. System Current Limits (I_{design}) 110 may be equal to cell and system design current. In some embodiments, System Current Limits (I_{design}) 110 may be a predetermined value based on one or more characteristics of cells 14, battery 10, system 30 (and/or any other component of system 30), a vehicle, etc. System Voltage (and/or Current) Limits 112 may refer to V_{pack} (and I_{pack}), where V_{pack}=Application voltage limits; and I_{pack}=(V_{pack}−OCV_{pack})/R_{pack}. OCV may refer to open circuit voltage, and R may refer to impedance. In some embodiments, pack refers to one or more cells 14 and/or one or more batteries 10. In some other embodiments, V_{pack} (and I_{pack}) may refer to the voltage (and/or current) of a plurality of cells 14, battery 10, and/or a group of batteries 10.

Cell voltage limits 114 may refer to V_{cell} (and I_{cell}), where V_{cell} is based on (and/or determine) safety and life (parameters) of battery 10. In some embodiments, I_{cell}=(V_{cell}−OCV_{cell})/R_{cell}.

Current limits 116 may be determined based on cell, pack, and/or design parameters (and/or any other parameters). In some embodiments, the value of current may be determined based on a minimum such as I=min (I_{cell}, Ipack, I_{design}) (i.e., the minimum value of I_{cell}, Ipack, I_{design}). In some other embodiments, voltage such as of battery 10 (or group of batteries 10) may be determined based on the value of current (e.g., based on a minimum value), impedance, open circuit voltage, etc. In some embodiments, the voltage value is determined to be V=OCV_{pack}+I*R_{pack}. Although some parameters such as current (I) and voltage (V) are associated with “design” “pack”, these values of I and V are not limited as such and may be the I and V measured at cell level, i.e., I_{cell} and V_{cell}, such as by BMS 16 via the plurality of leads 26.

In some embodiments, an SoC estimation/determination process (i.e., method) is performed, e.g., by BMS 16. In this nonlimiting example, SoC may be estimated and/or determined, such as by BMS 16, based on an initial value of SoC and/or current and/or C (i.e., battery capacity, which may be based on a reference capacity under a specific temperature and discharge rate). In some embodiments, SoC(t) may be the discharge current which is the positive in the equation below determined as:

$$SoC ( t ) = SoC ( t 0 ) - {\int }_{t 0}^{t} \frac{I ( t )}{C} dt$$

The determination may have (i.e., take into account, base the determination of SoC at least in part on) sources of errors such as sensor accuracy, current integration error, self-discharge, Coulomb efficiency, and initial SoC. SoC may also be estimated based on OCV correction. The determination of SoC based on OCV correction may have (i.e., take into account, base the determination of SoC at least in part on) sources of errors such as sensor inaccuracy, incomplete relaxation, lookup table inaccuracy.

In some other embodiments, performing OCV correction may comprise determining one or more OCV values based on SoC (%) and temperature (deg. C.). The determination of the one or more OCV values may be performed using a lookup table, e.g., the OCV values are looked up (e.g., found, estimated, etc.) in an array of data that maps input values (e.g., SoC (%) and temperature (deg. C.)) to output values (e.g., OCV values). The OCV lookup table values may be graphed such as in a three-dimensional graph, where the x-axis is temperature (deg. C.), the y-axis is SoC (%), and the z-axis is the OCV values.

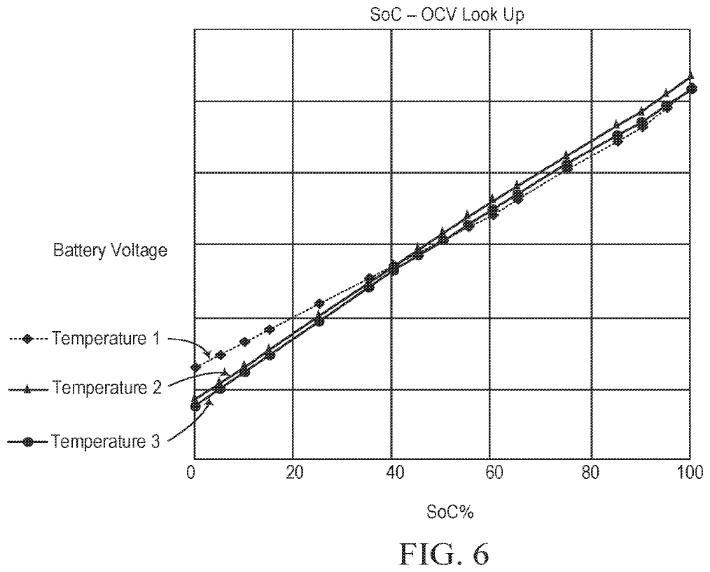

In some embodiments, performing OCV correction may comprise determining one or more OCV accuracy values based on SoC (%) and temperature (deg. C.). The determination of the one or more OCV accuracy values may be performed using a lookup table, e.g., the OCV accuracy values are looked up (e.g., found, estimated, etc.) in an array of data that maps input values (e.g., SoC (%) and temperature (deg. C.)) to output values (e.g., OCV accuracy values). The OCV lookup table accuracy values may be graphed such as in a three-dimensional graph, where the x-axis is temperature (deg. C.), the y-axis is SoC (%), and the z-axis is the OCV accuracy values. However, the embodiments of the present disclosure are not limited as such and may describe OCV lookup that may be graphed using any type of graph such as a two-dimensional graph. FIG. 6 shows an example SoC-OCV lookup graph. For example, for lead acid batteries such as Absorbent Glass Mat (AGM) lead acid batteries, estimating SoC based on the OCV reading is highly reliable when the battery 10 is given a predetermined rest time. During driving, the SoC can be updated with current integration method (i.e., electrical current integration method). Both methods can have various sources of errors. In some embodiments, the SoC estimation is based on the combination of both OCV correction and current integration methods to achieve optimum results.

In other words, refresh charge keeps the battery in the optimized state(s); SoH may be used for preventive replacement, e.g., by leveraging usage history and/or real time measurement; and abuse/faults can be tracked/communicated, e.g., on demand, per request, etc.

FIG. 7 shows a table including example messages according to some embodiments of the present disclosure. BMS 16 may be configured to determine at least one message of the example messages and/or transmit/receive the message(s). The message(s) may be associated with a lead acid battery such as an Absorbent Glass Mat (AGM) battery and/or one or more communication protocols/standards, e.g., Controller Area Network (CAN), Local Interconnect Network (LIN), Bluetooth, etc. The message(s) may include ButteryCurrent, BatteryVoltage, BatteryTemperature, MaximumDischargePower_100 ms, MaximumDischargePower_10 s, MaximumDischargePower_1 s, Refresh Charge, State of Heatlh (SoH), State of Charge (SoC), WakeupSource, External Command, DiagReq, and/or DiagRes.

BatteryCurrent and BatteryVoltage correspond to battery current and battery voltage, respectively, which may be reported and/or be measurement values. BatteryTemperature corresponds to battery temperature which may be an estimated value, e.g., based on temperature sensor measurements. MaximumDischargePower_100 ms (10 s, 1 s) corresponds to battery discharge power limit in the next period of time, e.g., 100 ms (1 s, 10 s, respectively) which may be reported by a state of function (SOF) algorithm such as performed by BMS 16. Refresh charge may be a feature for the purpose of keeping the battery at one or more battery states, e.g., optimum states. Battery states prevent the battery 10 from having accelerated degradation such as resulting from undercharging. A refresh charge being on (i.e., true, activated, 1, etc.) may indicate that the battery 10 shall (i.e., should, can, will) be fully charged such as according to recommendations provided by battery. The refresh charge request may be off (i.e., false, deactivated, 0, etc.) if the battery 10 has been charged to a battery state, e.g., one or more of the optimum states.

Further, SoH being on (i.e., true, activated, 1, etc.) may indicate that the battery 10 should be (i.e., can be, is recommended to be) replaced. For example, when SoH is on the battery may be in a state that indicates that replacing the battery is a course of action that keeps the battery 10 in a battery state, e.g., optimum state, in the long run and/or prevent damage to battery 10. State of charge (SoC) (e.g., SoC in % units) reports (i.e., indicates) battery state of charge. BMS 16 may be configured to transmit WakeupSource (e.g., type of wakeup requested). The specifics are to be determined with customers. The external command may be reserved for BMS 16 to receive one or more commands from device 36. DiagReqund and/or DiagRes correspond to diagnostics request and diagnostic response, respectively, and may be used in communication between BMS 16 and other devices/components, e.g., diagnostic tools. In one or more embodiments, any parameter, state, message, etc. may be transmitted to and/or received from any component of system 30, such as BMS 16, network 32, server 34, and/or device 36. BMS 16 can sample various sensors within battery 10 at a predetermined sampling rate and use the sensor data as a basis for determining corresponding parameters, states, etc.

In one nonlimiting example of one or more embodiments of the present disclosure, BMS 16 may be configured to measure one or more parameters, e.g., inputs such as current and/or voltage. BMS 16 may be also configured to determine another parameter, e.g., a state of health (SoH), state of function (SoF), state of charge (SoC), diagnostics parameters. Further, BMS 16 may be configured to determine a limit associated with one or more determined parameters, such as an SoF power limit. The SoF limit may be determined based on worst performing limits from (i.e., based on) one or more limits such as system limits, cell limits, and vehicle performing limits. SoC may be determined based on current integration and/or OCV correction and/or considering one or more error sources. In other words, one or more parameters and/or battery states may be determined and/or forecast (e.g., every predetermined time interval), which provide information about the battery that may be relevant to a user (and/or owner and/or manufacturer and/or service provider) of the battery.

For example, SoH may be determined to be on, e.g., based on other parameters, which may indicate a degraded battery state and that the battery should be replaced before a predetermined date/time. Any parameter (e.g., determined, measured, estimated) may be communicated (i.e., received/transmitted), e.g., using one or more communication protocol/standard such as CAN, Local Interconnect Network (LIN), Bluetooth, etc. The SoH indicating a degraded battery state may be communicated to: device 36 of a vehicle where the battery 10 is installed to avoid starting the engine of the vehicle using the degraded battery; a device associated with the user/owner of the battery 10; and/or the manufacturer of the battery for failure recording; and/or a service provider, e.g., to schedule a service appointment.

In some embodiments, BMS 16 may be configured to transmit vehicle and battery data to server 34 configured to run a fleet management application. In some other embodiments, BMS may be configured to measuring battery voltage and cell voltages and perform an action such as perform a diagnostic of an external circuit, over charging or experiencing extreme temperature which can damage the battery.

In some embodiments, one or more actions may be performed by BMS 16 such as to set BMS 16 at a low power mode (e.g., deeper sleep mode) without frequent wakeup until, BMS 16 first detects the battery current exceeding a threshold. The BMS 16 may enter into the deeper sleep mode if BMS 16 detects that the battery 10 is not being used after certain time. This can minimize the self-discharge rate during transportation, on shelf storage and airport parking.

In some other embodiments, vehicles having device 36, e.g., truck fleet configured with devices 36, may use the BMS 16 inside of an AGM battery which can preprocess battery data and save the battery data in the form of histograms. Additional information may be requested to a software application (e.g., of device 36, server 34), e.g., only on demand. This may reduce the cost associated with the data transmission.

In some embodiments, one or more communication protocols may be used by BMS 16, e.g., to perform one or more actions associated with the determination of SoF such as to communicate battery capabilities. For example, the following battery capability and/or information may be transmitted by BMS 16:
Minimum pulse/crank voltage associated with specific temperature and SoC conditions that are likely to be with the next crank/pulse usage;
Probabilities of successful crank/safety maneuver with specific temperature and SoC conditions that are likely to be with the next usage; and
Minimum SoC to ensure the successful crank/safety maneuver with specific temperature that are likely to be with the next usage.

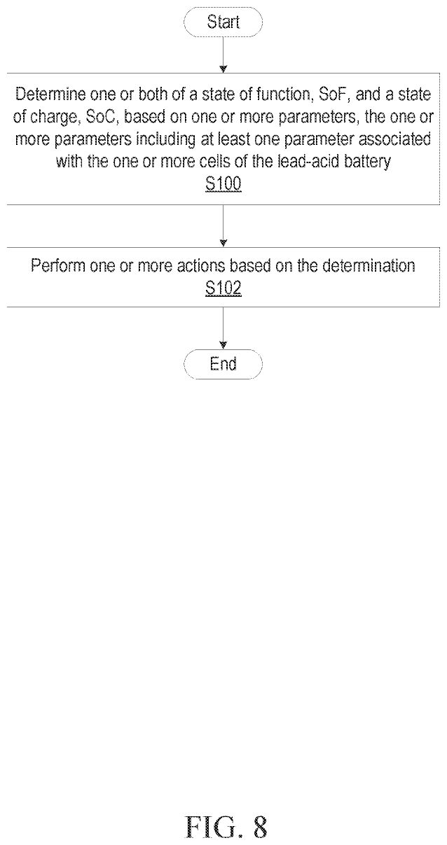

FIG. 8 shows an example method (e.g., in BMS 16). The BMS is electrically connectable to a lead-acid battery 10 having one or more cells 14. The method includes determining (Block S100) one or both of a state of function (SoF) and a state of charge (SoC) based on one or more parameters 100, where the one or more parameters 100 include at least one parameter 100 associated with the one or more cells 14 of the lead-acid battery 10, and performing (Block S102) one or more actions based on the determination.

In some embodiments, determining the SoF includes determining a design current of the one or more cells 14 based on one or more characteristics of the one or more cells 14.

In some other embodiments, determining the SoF further includes determining a pack current based on a pack voltage, a pack open circuit voltage (OCV) and a pack impedance corresponding to the one or more cells.

In some embodiments, determining the SoF further includes determining a cell current based on a cell voltage, a cell OCV, and a cell impedance corresponding to the one or more cells.

In some other embodiments, determining the SoF further comprises determining a current limit, where the current limit is a minimum of one or more of the design current, the pack current, and the cell current.

In some embodiments, determining the SoF further includes determining a voltage limit based on the current limit.

In some other embodiments, determining the SoF is based on a power limit determined based on the current limit and the voltage limit.

In some embodiments, the SoC is determined as:

$$SoC ( t ) = SoC ( t 0 ) - {\int }_{t 0}^{t} \frac{I ( t )}{Q ( t )} dt$$

SoC(t) being the SoC in time;
SoC(t0) being the SoC at a first time value
I(t) being a cell current in time; and
Q(t) being a capacity.

In some other embodiments, determining the SOC includes determining an OCV correction. The OCV correction is based on one or more OCV values. The one or more OCV values are based on a plurality of SoC percentages and a plurality of temperature values associated with the lead-acid battery 10.

In some embodiments, performing one or more actions includes transmitting a first message comprising one or both of the SoF and the SoC using a controller area network (CAN) protocol, transmitting a second message comprising at last one parameter associated with one or both of the SoF and the SoC, and performing a battery operation action.

Accordingly, the systems, apparatuses, methods (e.g., the algorithms) of the present disclosure are beneficial at least because battery reliability is improved by keeping the battery in one or more battery states (e.g., the optimized states), and battery preventative replacement can be indicated/alerted before battery failure. Further, battery abuse/faults (e.g., excessive engine starts, high loads, etc.) may also be tracked and/or communicated.

As will be appreciated by one of skill in the art, the concepts described herein may be embodied as a method, data processing system, computer program product and/or computer storage media storing an executable computer program. Accordingly, the concepts described herein may take the form of an entirely hardware embodiment, an entirely software embodiment or an embodiment combining software and hardware aspects all generally referred to herein as a “circuit” or “module.” Any process, step, action and/or functionality described herein may be performed by, and/or associated to, a corresponding module, which may be implemented in software and/or firmware and/or hardware. Furthermore, the disclosure may take the form of a computer program product on a tangible computer usable storage medium having computer program code embodied in the medium that can be executed by a computer. Any suitable tangible computer readable medium may be utilized including hard disks, CD-ROMs, electronic storage devices, optical storage devices, or magnetic storage devices.

Some embodiments may be described herein with reference to flowchart illustrations and/or block diagrams of methods, systems and computer program products. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer (to thereby create a special purpose computer), special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable memory or storage medium that can direct a computer or other programmable data processing apparatus to function in a particular manner, such that the instructions stored in the computer readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

It is to be understood that the functions/acts noted in the blocks may occur out of the order noted in the operational illustrations. For example, two blocks shown in succession may in fact be executed substantially concurrently or the blocks may sometimes be executed in the reverse order, depending upon the functionality/acts involved. Although some of the diagrams include arrows on communication paths to show a primary direction of communication, it is to be understood that communication may occur in the opposite direction to the depicted arrows.

Computer program code for carrying out operations of the concepts described herein may be written in an object oriented programming language such as Python, Java® or C++. However, the computer program code for carrying out operations of the disclosure may also be written in conventional procedural programming languages, such as the “C” programming language. The program code may execute entirely on the user's computer, partly on the user's computer, as a stand-alone software package, partly on the user's computer and partly on a remote computer or entirely on the remote computer. In the latter scenario, the remote computer may be connected to the user's computer through a local area network (LAN) or a wide area network (WAN), or the connection may be made to an external computer (for example, through the Internet using an Internet Service Provider).

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

It is understood that all specification values shown and described herein are non-limiting examples for implementations of batteries 10, cells 14, BMS 16, network 32, server 34, and/or device 36 constructed in accordance with the principles of the disclosure provided herein. It will be appreciated by persons skilled in the art that the present embodiments are not limited to what has been particularly shown and described herein above. In addition, unless mention was made above to the contrary, it should be noted that all of the accompanying drawings are not to scale. A variety of modifications and variations are possible in light of the above teachings and following claims.

1. A battery management system, BMS, electrically connectable to a lead-acid battery having one or more cells, the BMS comprising processing circuitry configured to:
determine one or both of a state of function, SoF, and a state of charge, SoC, based on one or more parameters, the one or more parameters including at least one parameter associated with the one or more cells of the lead-acid battery; and
perform one or more actions based on the determination.

2. The BMS of claim 1, wherein determining the SoF comprises determining a design current of the one or more cells based on one or more characteristics of the one or more cells.

3. The BMS of claim 2, wherein determining the SoF further comprises determining a pack current based on a pack voltage, a pack open circuit voltage, OCV, and a pack impedance corresponding to the one or more cells.

4. The BMS of claim 3, wherein determining the SoF further comprises determining a cell current based on a cell voltage, a cell OCV, and a cell impedance corresponding to the one or more cells.

5. The BMS of claim 4, wherein determining the SoF further comprises determining a current limit, the current limit being a minimum of one or more of the design current, the pack current, and the cell current.

6. The BMS of claim 5, wherein determining the SoF is based on a power limit determined based on the current limit and a voltage limit.

7. The BMS of claim 6, wherein determining the SoF further comprises determining a power limit based on the current limit and the voltage limit.

8. The BMS of claim 1, wherein the SoC is determined as:
$$SoC ( t ) = SoC ( t 0 ) - {\int }_{t 0}^{t} \frac{I ( t )}{Q ( t )} dt$$
SoC(t) being the SoC in time;
SoC(t0) being the SoC at a first time value
I(t) being a cell current in time; and
Q(t) being a capacity.

9. The BMS of claim 1, wherein determining the SOC comprises determining an open circuit voltage, OCV, correction, the OCV correction being based on one or more OCV values, the one or more OCV values being based on a plurality of SoC percentages, and a plurality of temperature values associated with the lead-acid battery.

10. The BMS of claim 1, wherein performing one or more actions comprises:
causing transmission of a first message comprising one or both of the SoF and the SoC using a controller area network, CAN, protocol;
causing transmission of a second message comprising at last one parameter associated with one or both of the SoF and the SoC; and
performing a battery operation action.

11. A lead-acid battery, the lead-acid battery comprising:
one or more cells;
one or more leads, each lead being electrically connected to one cell of the one or more cells;
a battery management system, BMS, electrically connected to the one or more cells via the one or more leads, the BMS comprising processing circuitry configured to:
determine one or both of a state of function, SoF, and a state of charge, SoC, based on one or more parameters, the one or more parameters including at least one parameter associated with the one or more cells; and
perform one or more actions based on the determination.

12. The lead-acid battery of claim 11, wherein determining the SoF comprises determining a design current of the one or more cells based on one or more characteristics of the one or more cells.

13. The lead-acid battery of claim 12, wherein determining the SoF further comprises determining a pack current based on a pack voltage, a pack open circuit voltage, OCV, and a pack impedance corresponding to the one or more cells.

14. The lead-acid battery of claim 13, wherein determining the SoF further comprises determining a cell current based on a cell voltage, a cell OCV, and a cell impedance corresponding to the one or more cells.

15. The lead-acid battery of claim 14, wherein determining the SoF further comprises determining a current limit, the current limit being a minimum of one or more of the design current, the pack current, and the cell current.

16. The lead-acid battery of claim 15, wherein determining the SoF further comprises determining a voltage limit based on the current limit.

17. The lead-acid battery of claim 16, wherein determining the SoF is based on a power limit determined based on the current limit and the voltage limit.

18. The lead-acid battery of claim 11, wherein the SoC is determined as:
$$SoC ( t ) = SoC ( t 0 ) - {\int }_{t 0}^{t} \frac{I ( t )}{Q ( t )} dt$$
SoC(t) being the SoC in time;
SoC(t) being the SoC at a first time value
I(t) being a cell current in time; and
Q(t) being a capacity.

19. The lead-acid battery of claim 11, wherein determining the SOC comprises determining an open circuit voltage, OCV, correction, the OCV correction being based on one or more OCV values, the one or more OCV values being based on a plurality of SoC percentages, and a plurality of temperature values associated with the lead-acid battery.

20. The lead-acid battery of claim 11, wherein performing one or more actions comprises:
causing transmission of a first message comprising one or both of the SoF and the SoC using a controller area network, CAN, protocol;
causing transmission of a second message comprising at last one parameter associated with one or both of the SoF and the SoC; and
performing a battery operation action.

21.-30. (canceled)
